(19) United States
(12) Patent Application Publication
(10) Pub. No.: US 2012/0064724 A1
(43) Pub. Date: Mar. 15, 2012

(54) Methods of Forming a Pattern of Semiconductor Devices

(76) Inventors: Bo-hee Lee, Gunpo-si (KR); Kyoung-mi Kim, Anyang-si (KR); Jeong-ju Park, Hwaseong-si (KR); Mi-ra Park, Seoul (KR); Jae-ho Kim, Yongin-si (KR); Young-ho Kim, Seongnam-si (KR)

(21) Appl. No.: 13/222,447

(22) Filed: Aug. 31, 2011

(30) Foreign Application Priority Data
Sep. 14, 2010 (KR) 10-2010-0089920

(51) Int. Cl. H01L 21/308

(52) U.S. Cl. 438/703; 257/E21.231

(57) ABSTRACT

Methods of forming a pattern of a semiconductor device including performing a double patterning process without using an atomic layer deposition (ALD) oxide film are provided. The methods may include forming a mask pattern on a substrate; forming a chemical attach process (CAP) material layer covering at least a portion of the mask pattern; forming a CAP adhesive layer by adhering at least a portion of the CAP material layer to the mask pattern by using a first baking process and a first development process; forming an interlayer covering at least a portion of the mask pattern and the CAP adhesive layer; and removing the mask pattern and the interlayer while allowing the CAP adhesive layer to remain by using a second baking process and a second development process.

### CROSS-REFERENCE TO RELATED APPLICATIONS

This application claims the benefit of Korean Patent Application No. 10-2010-0089920, filed on Sep. 14, 2010, in the Korean Intellectual Property Office, the disclosure of which is incorporated by reference herein in its entirety.

### FIELD OF THE INVENTION

The inventive concept relates to methods of manufacturing a semiconductor device, and more particularly, to methods of forming a fine pattern of a semiconductor device which may overcome a resolution limit of an existing exposure.

### BACKGROUND

As design rules of semiconductor devices have decreased, a photolithography process used to form a fine-pitch pattern in the semiconductor device has reached or will reach its resolution limit. In an effort to overcome the resolution limit of the photolithography process, a method of forming a fine mask pattern having a fine pitch by using a double patterning technology (DPT) process has been suggested.

A conventional DPT process requires the use of a plurality of chemical vapor deposition (CVD) processes, and is complex. In particular, a conventional DPT process uses an atomic layer deposition (ALD) oxide film. However, a device for forming an ALD oxide film can be very expensive, and the process turn-around time (TAT) can be very long. Also, since the number of layers on which a fine pattern is to be formed has continuously increased as devices are miniaturized, to use a conventional DPT process in forming all fine patterns is typically costly and time-consuming.

### SUMMARY

The inventive concept provides methods of forming a pattern of a semiconductor device which may perform a double patterning process without using an atomic layer deposition (ALD) oxide film.

According to an aspect of the inventive concept, there is provided a method of forming a pattern of a semiconductor device, the method may include forming a first mask pattern on a substrate; forming a second mask pattern that contacts a surface of the first mask pattern; converting the first mask pattern into a layer comprising an acid; and removing the layer including the acid. Converting the first mask pattern into the layer including the acid includes utilizing a thermal, for example, heat, treatment process. The thermal treatment process facilitates diffusion of an acid component to provide a layer including acid. The thermal treatment process may be a baking process.

According to a further aspect of the inventive concept, there is provided a method of forming a pattern of a semiconductor device, the method may include forming a mask pattern on a substrate; forming a chemical attach process (CAP) material layer which covers at least a portion of the mask pattern; forming a CAP adhesive layer by adhering at least a portion of the CAP material layer to the mask pattern by using a first baking process and a first development process; forming an interlayer which covers at least a portion of the mask pattern and the CAP adhesive layer; and removing the mask pattern and the interlayer while allowing the CAP adhesive layer to remain by using a second baking process and a second development process.

The CAP material layer may be formed of a resolution enhancement lithography assisted by chemical shrink (RELACS) material, wherein the CAP adhesive layer is formed by cross-linking at least a portion of the CAP material layer to surfaces of the mask pattern by using the first baking process. Formation of the mask pattern may include forming a resist layer containing a photoacid generator (PAG) on the substrate; and patterning the resist layer by using an exposure process and a development process, wherein, in the first baking process, the CAP adhesive layer is formed on side surfaces of the mask pattern on which an acid remains.

The interlayer may be formed of a material containing a thermal acid generator (TAG). In the second baking process, an acid may be generated in the interlayer, and the acid is diffused into the mask pattern.

The CAP material layer and the interlayer may be formed by using a spin coating process. The substrate may include a target layer on which a target pattern is to be formed; wherein the mask pattern is formed on the target layer, and wherein after removal of the mask pattern, the method includes etching the target layer by using the CAP adhesive layer as a mask.

According to another aspect of the inventive concept, there is provided a method of forming a pattern of a semiconductor device, the method may include forming a resist layer containing a PAG on a substrate; forming a mask pattern by patterning the resist layer by using an exposure process and a first development process; forming a CAP material layer, which covers at least a portion of the mask pattern, on the substrate; forming a CAP adhesive layer by adhering at least a portion of the CAP material layer to the mask pattern by using a first baking process and a second development process; forming a TAG-containing interlayer, which covers at least a portion of the mask pattern and the CAP adhesive layer, on the substrate; forming an acid diffusion region on the TAG-containing interlayer and the mask pattern by using a second baking process; and forming a CAP adhesive pattern by removing the acid diffusion region by using a third development process.

According to another aspect of the inventive concept, there is provided a method of forming a pattern of a semiconductor device, the method may include forming a resist layer containing a PAG on a substrate; forming a mask pattern by patterning the resist layer by using an exposure process and a first development process; forming a CAP material layer, which covers at least a portion of the mask pattern, on the substrate; forming a CAP adhesive layer by adhering at least a portion of the CAP material layer to the mask pattern by using a first baking process and a second development process; converting the mask pattern into an acid diffusion region by using a second baking process; and forming a CAP adhesive pattern by removing the acid diffusion region while allowing the CAP adhesive layer to remain by using a third development process.

The CAP material layer may be formed of a RELACS material containing a TAG, wherein, in the first baking process, at least a portion of the CAP material layer is cross-linked to side surfaces of the mask pattern on which an acid remains to form the CAP adhesive layer. In the first baking process, an acid may be not generated in the CAP adhesive layer, wherein, in the second baking process, an acid is generated in the CAP adhesive layer, and is diffused into the mask pattern so that the mask pattern is converted into an acid diffusion region.

### BRIEF DESCRIPTION OF THE DRAWINGS

Exemplary embodiments of the inventive concept will be more clearly understood from the following detailed description taken in conjunction with the accompanying drawings in which:

FIGS. 1 through 7 are cross-sectional views illustrating a method of forming a pattern of a semiconductor device, according to an embodiment of the inventive concept;

FIG. 8 is a cross-sectional view illustrating a baking process and a thermal acid generator (TAG) diffusion process of FIG. 5;

FIGS. 9 through 11 are cross-sectional views illustrating a method of forming a pattern of a semiconductor device, according to another embodiment of the inventive concept; and

FIG. 12 is a cross-sectional view illustrating a baking process and a TAG diffusion process of FIG. 11.

### DETAILED DESCRIPTION OF THE EMBODIMENTS

The inventive concept will now be described more fully with reference to the accompanying drawings, in which exemplary embodiments of the inventive concept are shown.

It will also be understood that when a layer is referred to as being “on” another layer or a substrate, it can be directly on the other layer or the substrate, or intervening layers may also be present therebetween. In the following description of the inventive concept, the sizes of constituent elements shown in the drawings may be exaggerated, if needed, or sometimes the elements may be omitted for a better understanding of the inventive concept. Like reference numerals denote like elements in the drawings. Also, as used herein, “and/or” refers to and encompasses any and all possible combinations of one or more of the associated listed items. The terms used in the specification and the claims should not be limited to conventional or lexical meaning and should be construed as having meanings and concepts corresponding to the technical idea of the inventive concept in order to most appropriately describe the inventive concept.

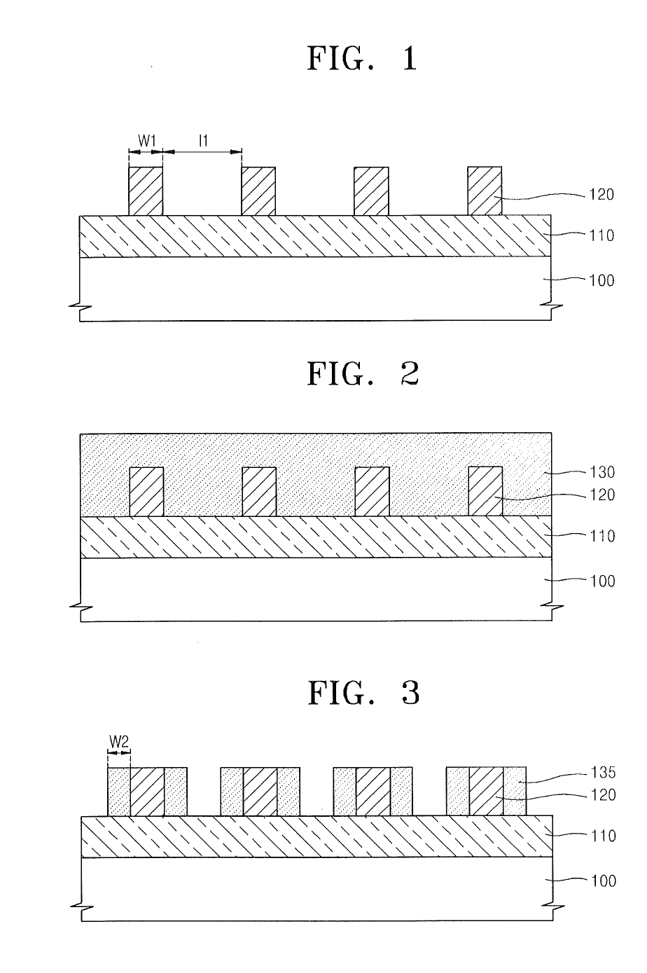

FIGS. 1 through 7 are cross-sectional views illustrating a method of forming a pattern of a semiconductor device, according to an embodiment of the inventive concept.

Referring to FIG. 1, a target layer 110 is formed on a substrate 100, and a mask pattern 120 having a predetermined shape is formed on the target layer 110.

The substrate 100 may be a semiconductor substrate. Examples of the semiconductor substrate may include a group IV semiconductor substrate, a group III-V compound semiconductor substrate, and a group II-VI oxide semiconductor substrate. Examples of the group IV semiconductor substrate may include a silicon substrate, a germanium substrate, and a silicon-germanium substrate. The substrate 100 may include a bulk wafer or an epitaxial layer. In FIG. 1, active regions, device isolation films, a conductive layer, an insulating layer, etc. may be formed on the substrate 100.

The target layer 110, which is a layer on which a final target pattern is to be formed, may be formed of any of various materials according to the use of the final target pattern. If a gate electrode, that is, a gate line, is formed on the substrate 100, the target layer 110 may include a conductive layer such as a polysilicon layer or a stack including a doped polysilicon layer and a metal silicide layer. If a bit line is formed on the substrate 100, the target layer 110 may be formed of a metal, such as tungsten or aluminum.

If a fine pattern is formed finally on the substrate 100, the target layer 110 may be omitted. For example, when the method of the present embodiment is used in order to define an active region on the substrate 100, the target layer 110 may be omitted.

Elements of the mask pattern 120 having a first width W1 and a first interval I1 are formed on the target layer 110 to extend parallel to one another.

The mask pattern 120 may be a resist pattern obtained from a general resist material. For example, the mask pattern 120, that is, the resist pattern with an opening through which a top surface of the target layer 110 is exposed as much as the first interval I1 may be formed by coating a resist material on the target layer 110 to form a resist layer and exposing and developing the resist layer according to a general photolithography process.

The mask pattern 120 may be formed of a chemically amplified positive resist material containing a photoacid generator (PAG). For example, the mask pattern 120 may be formed of a resist material for a KrF excimer laser (248 nm), a resist material for an ArF excimer laser (193 nm), or a resist material for a F₂ excimer laser (157 nm). A chemically amplified positive resist may include a base component of which alkali solubility is changed by the action of an acid and a PAG that generates an acid due to exposure. For example, since the chemically amplified positive resist includes a resin that increases an alkali solubility due to the action of an acid, once an acid is generated by the PAG due to exposure, an exposed portion is changed to be alkali soluble. Next, when a development process is performed by using an alkali developer, e.g., tetra methyl ammonium hydroxide (TMAH), the exposed portion is dissolved and removed.

Here, the base component, which is an organic compound for forming a film, may be an organic compound having a molecular weight more than 500. Examples of the base component may include a low molecular weight organic compound having a molecular weight of 500 to 2000 or a polymer resin having a molecular weight more than 2000. The base component has an acid dissociable dissolution inhibiting group, and an alkali solubility of the base component is increased by the action of an acid. Although the chemically amplified positive resist including the base component is alkali insoluble before exposure, when an acid is generated from the PAG due to exposure to form a resist pattern, since the acid dissociable dissolution inhibiting group is dissociated by the action of the acid, the chemically amplified positive resist containing the base component is changed to become alkali soluble.

Accordingly, in order to form a resist pattern, when a chemically amplified positive resist material is coated on a substrate and selectively exposed, since an exposed portion is changed to an alkali soluble part whereas an unexposed portion remains as an alkali insoluble portion, alkali development is carried out only on the exposed portion.

The proportion of a structural unit having an acid dissociable dissolution inhibiting group in the polymer resin is preferably within a range of 20 to 80 mol %, more preferably 20 to 70 mol %, and still more preferably 30 to 60 mol % based on a combined total of all structural units constituting the polymer resin. In detail, the polymer resin may be a novolak resin having an acid dissociable dissolution inhibiting group, a hydroxystyrene-based resin, an (α—lower alkyl) acrylate ester resin, or a copolymer resin containing a structural unit derived from hydroxystyrene and a structural unit derived from an (α—lower alkyl) acrylate ester.

The PAG may be selected from well-known acid generators. Examples of the well-known acid generators include an onium salt-based acid generator such as iodonium salt and sulfonium salt, an oxime sulfonate-based acid generator, a diazomethane-based acid generator such as bisalkyl or bisaryl sulfonyl diazomethane and poly(bis-sulfonyl) diazomethane, a nitrobenzylsulnate-based acid generator, an iminosulfonate-based acid generator, and a disulfone-based acid generator. A single acid generator may be used or a combination of two or more acid generators may be used. The acid generator may be used in a range from 1 to 20 mass % or from 2 to 10 mass % based on the entire content of the base component.

In order to improve a pattern shape, stability over time, etc., the chemically amplified resist material may be mixed with a nitrogen-containing organic compound (referred to as “a first arbitrary component”). Any of various well-known components may be arbitrarily used as the first arbitrary component. In particular, as the first arbitrary component, a secondary aliphatic amine or a tertiary aliphatic amine may be used. The first arbitrary component may be used in a range of 0.01 to 5.0 mass % based on the entire content of the base component.

Meanwhile, the chemically amplified resist material may contain an organic carboxylic acid or a phosphorus oxo acid or a derivative thereof (referred to as “a second arbitrary component”) in order to prevent deterioration in sensitivity due to the mixture with the first arbitrary component, and in order to improve a pattern shape, stability, etc. In addition, either one or both of the first arbitrary component and the second arbitrary component may be used. The second arbitrary component may be used in a range of 0.01 to 5.0 mass % based on the entire content of the base component.

The chemically amplified resist material may contain a miscible additive, according to need, for example, an additive resin for improving the properties of a coating film of a resist material, a surfactant for improving coating properties, a dissolution inhibitor, a plasticizer, a stabilizer, a colorant, and/or a halation prevention agent.

The chemically amplified resist material may be prepared by dissolving each of the components in an organic solvent. The organic solvent may dissolve the components to generate a uniform solution. Either one, or two or more well-known resist material organic solvents may be used as the organic solvent. Although there are no particular restrictions on the quantity of the organic solvent used, a quantity that produces a suitable concentration for application of the chemically amplified resist material to a supporter is used.

Although not shown, before the mask pattern 120 is formed, a bottom anti-reflection coating (BARC) layer may be further formed on the target layer 110.

Referring to FIG. 2, a chemical attach process (CAP) material layer 130 is formed on a side wall and the top surface of the target layer 110 on which the mask pattern 120 is formed.

The CAP material layer 130 may be formed of a polymer. For example, the polymer may include a repeating unit including at least one monomer unit selected from the group consisting of an acrylamide type monomer unit, a vinyl type monomer unit, an alkylene glycol type monomer unit, a maleic anhydride monomer unit, an ethyleneimine monomer unit, a monomer unit including an oxazoline group, an acrylonitrile monomer unit, an allylamide monomer unit, a 3,4-dihydropyran monomer unit, and/or a 2,3-dihydropyran monomer unit.

In particular, the CAP material layer 130 may be formed by spin coating a resolution enhancement lithography assisted by chemical shrink (RELACS) material or an SH-114 (available from AZ Electronic Materials) on an exposed surface of the mask pattern 120.

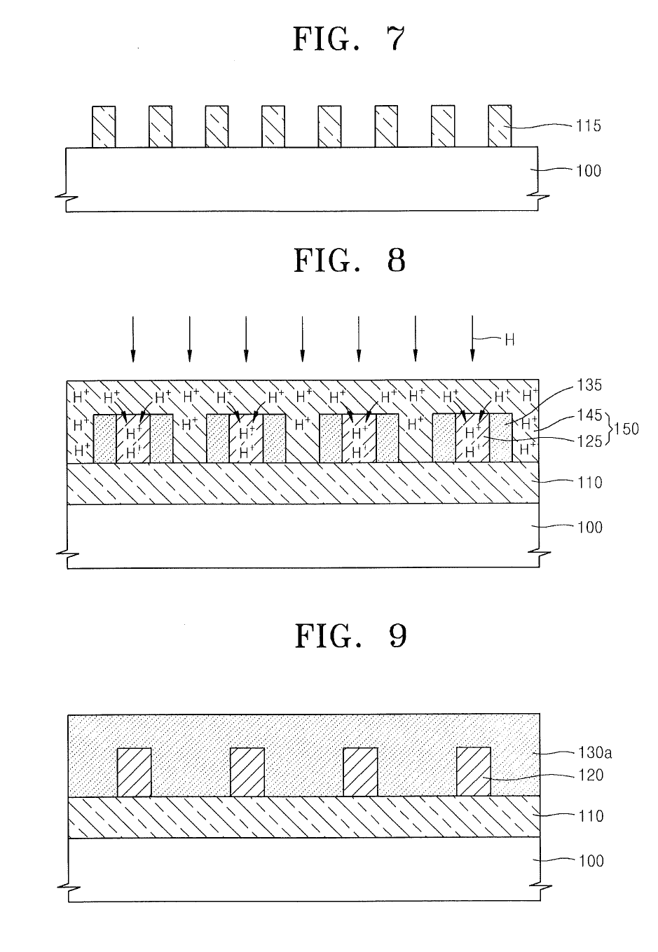

If necessary, the CAP material layer 130 may include an acid source including an acid or a potential acid. For example, the CAP material layer 130 may include a mixture of a polymer and an acid source. A case where the CAP material layer 130 includes an acid or a potential acid will be explained in detail with reference to FIG. 9.

Referring to FIG. 3, a CAP adhesive layer 135 having a second width W2 is formed at side walls of the mask pattern 120 by baking and developing the CAP material layer 130.

For example, in order to form the CAP adhesive layer 135, the CAP material layer formed of a water soluble polymer as described above may be coated on an exposed surface of the mask pattern 120, and then a resultant structure may be thermally treated, that is, baked.

For example, the CAP adhesive layer 135 may be formed by spin coating a RELACS material on the exposed surface of the mask pattern 120 and baking a resultant structure at a predetermined temperature, for example, a temperature of about 100 to 130° C., for a predetermined period of time, e.g., for about 20 to 70 seconds.

In this case, since an acid remaining on surfaces of the mask pattern 120 acts as a catalyst, the RELACS™ material may be cross-linked to the surfaces of the mask pattern 120 to form the CAP adhesive layer 135. Meanwhile, since the surfaces of the mask pattern 120 on which the acid remains are side surfaces of the mask pattern 120 contacting an exposed part and no acid exists on a top surface of the mask pattern 120, the CAP adhesive layer 135 may be formed only on the side surfaces, that is, the side walls, of the mask pattern 120.

Meanwhile, even when the CAP material layer 130 is formed of a mixture of the RELACS material and one of acid sources, the CAP adhesive layer 135 may be formed by using the above baking process.

After the CAP adhesive layer 135 is formed, at least a portion of the CAP material layer 130 which is not cross-linked and remains on the CAP adhesive layer 135 and the top surface of the mask pattern 120 may be removed by using a development process. For example, at least a portion of the CAP material layer 130 may be removed by using any solvent selected from the group Consisting of water, an organic solvent, a mixture of water and an organic solvent, and a developer.

Referring to FIG. 4, an interlayer 140, which covers the mask pattern 120 and the CAP adhesive layer 135, is formed on the target layer 110 by using a spin coating process.

The interlayer 140 may be formed of a chemically amplified resist material containing a thermal acid generator (TAG). That is, the interlayer 140 may include a base component of which alkali solubility is changed by the action of an acid and a TAG that generates an acid due to heat. Representative examples of the interlayer 140 may include an ICE024 (available from AZ Electronic Materials).

The base component has been described when the mask pattern 120 was described, and thus an explanation thereof will not be given.

The TAG of the interlayer 140 may include an aliphatic or alicyclic compound. For example, the TAG may include at least one compound selected from the group consisting of a carbonate ester, sulfonate ester, and phosphate ester.

In more detail, the TAG may include at least one compound selected from the group consisting of cyclohexyl nonafluorobutanesulfonate, norbornyl nonafluorobutanesulfonate, tricyclodecanyl nonafluorobutanesulfonate, adamantyl nonafluorobutanesulfonate, cyclohexyl nonafluorobutanecarbonate, norbornyl nonafluorobutanecarbonate, tricyclodecanyl nonafluorobutanecarbonate, adamantyl nonafluorobutanecarbonate, cyclohexyl nonafluorobutanephosphonate, norbornyl nonafluorobutanephosphonate, tricyclodecanyl nonafluorobutanephosphonate, and adamantyl nonafluorobutanephosphonate.

If the interlayer 140 includes a mixture of a base component and a TAG, the TAG may be used in a range of 0.01 to 50 mass % based on the entire content of the base component.

Referring to FIG. 5, after the interlayer 140 is formed, heat treatment H1, that is, a baking process, is performed. Due to the baking process, the TAG in the interlayer 140 generates an acid, and the acid is diffused into the interlayer 140 and the mask pattern 120, to form an acid diffusion region 150. The heat treatment H1, that is, the baking process, for forming the acid diffusion region 150 may be performed at a temperature of about 25 to 200° C. Here, 145 and 125 mean changed interlayer and mask pattern due to the acid diffusion.

In more detail, a process of forming the acid diffusion region 150 may include a process of generating an acid from the TAG included in the interlayer 140 and a process of diffusing the generated acid, and the two processes may be successively performed. Meanwhile, of course, a lower limit of the temperature of the heat treatment should be higher than a temperature at which each TAG generates an acid according to a component of the TAG.

Referring to FIG. 6, the acid diffusion region 150, that is, the interlayer 140 and the mask pattern 120, of which solubility is increased due to the acid, is dissolved and removed by using a developer. For example, the acid diffusion region 150 may be removed by using any one solvent of water, an organic solvent, a mixture of water and an organic solvent, and a developer. Here, the developer may be TMAH.

Because the acid diffusion region 150 is removed, only the CAP adhesive layer 135 remains on the target layer 110, and acts as a mask for etching the target layer 110. The remaining CAP adhesive layer 135 may maintain the same second width W2 as that of its initial CAP adhesive layer 135. Meanwhile, an interval between elements of the CAP adhesive layer 135 may include a second interval I2 corresponding to a width of the mask pattern 120 and a third interval I3 obtained by subtracting double the second width W2 from the first interval I1 between the elements of the mask pattern 120. Of course, the second interval I2 and the third interval I3 may be the same by adjusting the first width W1 of the mask pattern 120 and the first interval I1 between the elements of the mask pattern 120 when the mask pattern 120 is formed or by adjusting the second width W2 of the CAP adhesive layer 135 when the CAP adhesive layer 135 is subsequently formed.

Referring to FIG. 7, a final target pattern 115 is formed by etching the target layer 110 by using the CAP adhesive layer 135 as an etch mask. After the target pattern 115 is formed, the CAP adhesive layer 135 remaining on the target pattern 115, that is, a fine pattern is removed. In order to remove the CAP adhesive layer 135, ashing or striping may be used.

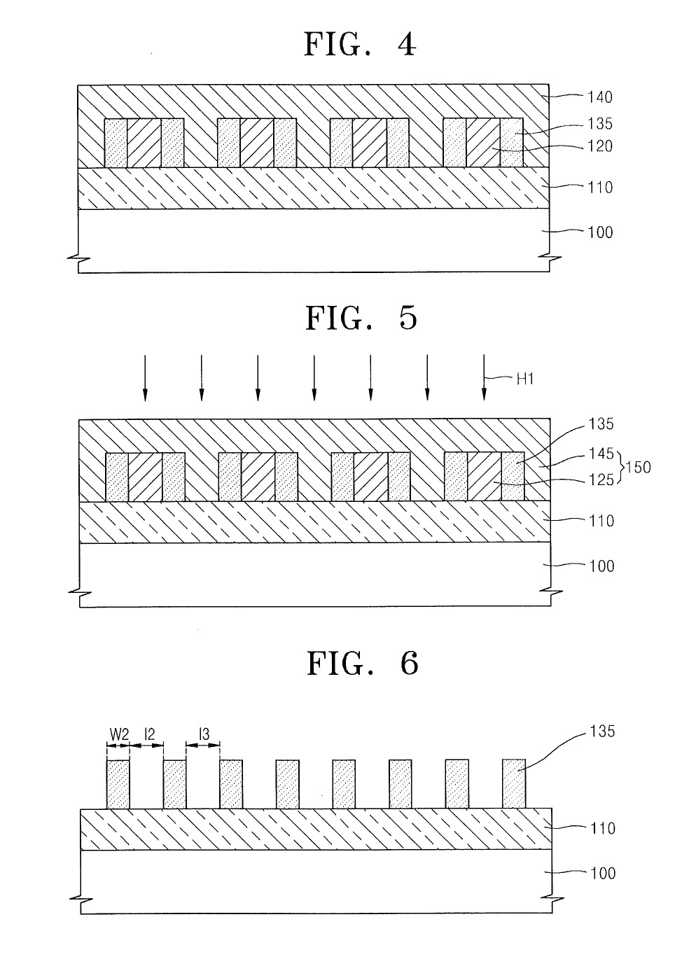

FIG. 8 is a cross-sectional view illustrating a baking process and a TAG diffusion process of FIG. 5.

As shown in FIG. 8, when a heat treatment H1, that is, a baking process, is performed on the interlayer 140, an acid, for example, H⁺, is generated in the TAG included in the interlayer 140, the generated H⁺ is diffused to the interlayer 140 and the mask pattern 120 to dissociate the dissociable dissolution inhibiting group of the base component, and the interlayer 140 and the mask pattern 120 are changed to be alkali soluble. The interlayer 140 and the mask pattern 120 changed to be alkali soluble may be easily dissolved and removed in an alkali developer.

FIGS. 9 through 11 are cross-sectional views illustrating a method of forming a pattern of a semiconductor device, according to another embodiment of the inventive concept. An explanation of the same processes as those described with reference to FIGS. 1 through 7 will not be provided.

Referring to FIGS. 9 and 10, processes in FIGS. 9 and 10 are similar to the processes in FIGS. 2 and 3. However, a component constituting a CAP material layer 130a or a CAP adhesive layer 135a is different from that of the CAP material layer 130 or the CAP adhesive layer 135 of FIG. 2 or 3.

That is, in the present embodiment, the CAP material layer 130a includes an acid source, such as an acid or a potential acid. The CAP material layer 130a may include a mixture of a polymer and an acid source. A potential acid included in the CAP material layer 130a may be a TAG that generates an acid due to heat.

The TAG of the CAP material layer 130a may include an aliphatic or alicyclic compound like the TAG included in the interlayer 140.

Meanwhile, the CAP material layer 130a may include a polymer compound that is insoluble in a developer, instead of a base component of which solubility is changed by an acid, unlike the interlayer 140. Accordingly, even when an acid is generated, solubility to a developer is not increased.

In FIG. 9, the CAP material layer 130a including the TAG is formed to cover at least a portion of the mask pattern 120, and in FIG. 10, the CAP adhesive layer 135a is formed by using a baking process and a development process. However, in the baking process of FIG. 10, the CAP material layer 130a may be cross-linked to surfaces of the mask pattern 120, and heat treatment may be performed at a process temperature that does not generate an acid in the TAG included in the CAP material layer 130a. Accordingly, the CAP material layer 130a may include the TAG of which an acid generating temperature is relatively high.

Referring to FIG. 11, after the CAP adhesive layer 135a is formed, a second baking process is performed. In the second baking process, an acid may be generated in the TAG in the CAP adhesive layer 135a and may be diffused to the mask pattern 120. Accordingly, in the second baking process, heat treatment H2 may be performed at a process temperature that is high enough to generate an acid in the TAG in the CAP adhesive layer 135a. Due to the diffusion of the acid, the mask pattern 120 is converted to an acid diffusion region. That is, the acid dissociable dissolution inhibiting group of the base component in the mask pattern 120 is dissociated, and thus, the mask pattern 120 is changed to become alkali soluble. A subsequent process is the same as that in FIGS. 6 and 7.

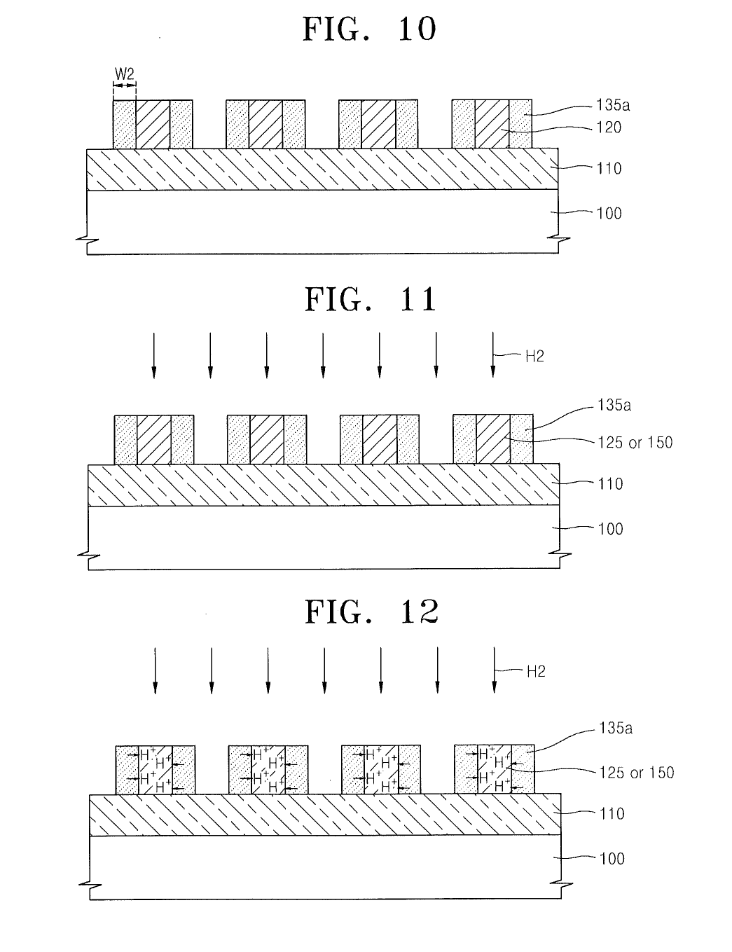

FIG. 12 is a cross-sectional view illustrating a baking process and a TAG diffusion process of FIG. 11.

As shown in FIG. 12, when heat treatment, that is, a baking process, is performed on the CAP adhesive layer 135a, an acid, for example, H⁺, is generated in the TAG included in the CAP adhesive layer 135a, the generated H⁺ is diffused to the mask pattern 120 to dissociate the acid dissociable dissolution inhibiting group of the base component, and the mask pattern 120 is changed to become alkali soluble. The mask pattern 120 changed to be alkali soluble may be more easily dissolved and removed in an alkali developer.

While the inventive concept has been particularly shown and described with reference to exemplary embodiments thereof, it will be understood that various changes in form and details may be made therein without departing from the spirit and scope of the following claims.

What is claimed is:

1. A method of forming a pattern of a semiconductor device, the method comprising:
forming a second mask pattern that contacts at least a portion of a first mask pattern on a substrate;
converting the first mask pattern into a layer comprising an acid;
removing the layer comprising the acid.

2. The method of claim 1, wherein an acid diffuses into the first mask pattern subsequent to forming the second mask pattern.

3. The method of claim 1, wherein converting the first mask pattern into the layer comprising the acid comprises a heat treatment process.

4. A method of forming a pattern of a semiconductor device, the method comprising:
forming a chemical attach process (CAP) material layer on at least a portion of a mask pattern on a substrate;
forming a CAP adhesive layer by adhering at least a portion of the CAP material layer to the mask pattern by using a first baking process and a first development process;
forming an interlayer on at least a portion of the mask pattern and the CAP adhesive layer; and
removing the mask pattern and the interlayer while allowing the CAP adhesive layer to remain by using a second baking process and a second development process.

5. The method of claim 4, wherein the CAP material layer is formed of a resolution enhancement lithography assisted by chemical shrink (RELACS) material, and the CAP adhesive layer is formed by cross-linking at least a portion of the CAP material layer to at least a surface of the mask pattern by using the first baking process.

6. The method of claim 5, wherein forming the mask pattern comprises:
forming a resist layer comprising a photoacid generator (PAG) on the substrate; and
patterning the resist layer by using an exposure process and a development process, wherein in the first baking process, the CAP adhesive layer is formed on a surface of the mask pattern on which an acid remains.

7. The method of claim 4, wherein the interlayer is formed of a material comprising a thermal acid generator (TAG).

8. The method of claim 7, wherein, in the second baking process, an acid is generated in the interlayer, and the acid is diffused into the mask pattern.

9. The method of claim 8, wherein, in the second development process, the mask pattern and the interlayer comprising the acid are dissolved and removed in a developer.

10. The method of claim 4, wherein the CAP material layer and the interlayer are formed by using a spin coating process.

11. The method of claim 4, wherein the substrate comprises a target layer on which a target pattern is to be formed;
wherein the mask pattern is formed on the target layer, and wherein after removal of the mask pattern, the method comprises etching the target layer by using the CAP adhesive layer as a mask.

12. The method of claim 11, wherein before forming the mask pattern, the method comprises forming an anti-reflection film on the target layer.

13. The method of claim 4, wherein the first baking process is performed at a temperature of 100 to 130° C., and/or the second baking process is performed at a temperature of 25 to 200° C.

14. A method of forming a pattern of a semiconductor device, the method comprising:
forming a mask pattern by patterning a resist layer comprising a photoacid generator (PAG) on a substrate by using an exposure process and a first development process;
forming a chemical attach process (CAP) material layer on the mask pattern, on the substrate;
forming a CAP adhesive layer by adhering at least a portion of the CAP material layer to the mask pattern by using a first baking process and a second development process;
converting the mask pattern into an acid diffusion region by using a second baking process; and
forming a CAP adhesive pattern by removing the acid diffusion region while allowing the CAP adhesive layer to remain by using a third development process.

15. The method of claim 14, wherein the CAP material layer is formed of a resolution enhancement lithography assisted by chemical shrink (RELACS) material containing a thermal acid generator (TAG),
wherein, in the first baking process, at least a portion of the CAP material layer is cross-linked to a surface of the mask pattern on which an acid remains to form the CAP adhesive layer.

16. The method of claim 15, wherein, in the first baking process, an acid is not generated in the CAP adhesive layer, and, in the second baking process, an acid is generated in the CAP adhesive layer and is diffused into the mask pattern so that the mask pattern is converted into the acid diffusion region.

17. The method of claim 14, wherein the CAP material layer is formed by using a spin coating process.

18. The method of claim 14, wherein the substrate comprises a target layer on which a pattern is to be formed and the mask pattern is formed on the target layer, and subsequent to forming the CAP adhesive pattern, the method comprises etching the target layer by using the CAP adhesive pattern as a mask.
